(19) United States
(12) Patent Application Publication
(10) Pub. No.: US 2002/0061647 A1
(43) Pub. Date: May 23, 2002

(54) METHOD FOR MANUFACTURING A SEMICONDUCTOR DEVICE INCLUDING TREATMENT OF SUBSTRATE AND APPARATUS FOR TREATMENT OF SUBSTRATE

(76) Inventors: TOMOKAZU KAWAMOTO, KANAGAWA (JP); SHINJI KUZUYA, KANAGAWA (JP)

Correspondence Address: ARMSTRONG,WESTERMAN & HATTORI, LLP, 1725 K STREET, NW., SUITE 1000, WASHINGTON, DC, 20006, US

(21) Appl. No.: 08/928,466

(22) Filed: Sep. 12, 1997

(30) Foreign Application Priority Data
Dec. 20, 1996 (JP) 8-341970

(51) Int. Cl. H01L 21/302; H01L 21/461

(52) U.S. Cl. 438/689

(57) ABSTRACT

A method for the treatment of a substrate is disclosed which comprises a step of washing the substrate as immersed in the liquid held in a one-bath type liquid tank, pulling up the substrate from within the liquid tank into the atmosphere of an inert gas, and drying the substrate in the atmosphere of the inert gas.

### BACKGROUND OF THE INVENTION

1. Field of the Invention

This invention relates to a method for the treatment of a substrate and an apparatus for the treatment of a substrate and more particularly relates to a method for the treatment of a substrate including a step of removing an oxide film from the surface of the substrate, a step of washing the substrate or the film, and the like and an apparatus for the treatment of the substrate.

2. Description of the Prior Art

In the process for the production of a semiconductor device, for the purpose of preventing the surface of a semiconductor wafer from being polluted thereby allaying the contact resistance and improving the reliability of the gate oxide film of an MOS transistor, the practice of washing the wet surface of the wafer with a chemical solution and deionized water and then drying the washed wafer surface as shown in FIGS. 1A to 1D and FIG. 2 has been in vogue.

First, with a liquid tank 102 set in place within an empty space enclosed with a chamber 101 as shown in FIG. 1A, a wafer 104 is washed with a chemical solution 103 held in the liquid tank 102 and then the introduction of isopropyl alcohol (hereinafter referred to briefly as “IPA”) into the ambience enveloping the liquid tank 102 is started. Subsequently, the wafer 104 is pulled up out of the liquid tank 102 as shown in FIG. 1B and then is blown with the IPA to expel the liquid on the surface of the wafer 104 together with the IPA by vaporization to dry the surface. Then, the surface of the wafer 104 is further dried by decompressing the interior of the chamber 101 as shown in FIG. 1C thereby heightening the volatility of the liquid on the surface of the wafer 104.

Thereafter, the interior of the chamber 101 is caused to resume the atmospheric pressure as shown in FIG. 1D and then the wafer 104 is extracted from the chamber 101.

Incidentally, the chemical solution 103 in the liquid tank 102 is discharged therefrom after the wafer 104 has been pulled up out of the liquid tank 102.

The apparatus which is used for performing the washing by the procedure mentioned above is generally operated batchwise.

Now that the trend of semiconductor wafers toward a larger diameter has been accelerated for the purpose of improving the efficiency of the production of semiconductor devices, however, the apparatus designed for sheet-fed washing is expected to find acceptance on account of space when the use of semiconductor wafers, 12 inches in diameter, begins in the near future.

As the sheet-fed type washing device, a dry washing apparatus constructed as illustrated in FIG. 3, for example, is known. This dry washing apparatus has a shower head 112 disposed as directed toward a semiconductor wafer 110 inside a chamber 111, which is provided with a gas outlet 113. The semiconductor wafer 110 is exposed as kept rotated by a spinner 114 inside the chamber 111 to a gasified chemical liquid such as hydrofluoric acid spouted from the shower head 112. A feed pipe 116 for feeding water for the washing and ozone is inserted into the chamber 111.

When this dry washing apparatus is utilized for removing the silicon oxide film on the surface of the silicon wafer 110, the removal of the silicon oxide film is attained by the use of hydrofluoric anhydride which is fed from the shower head 112 to the silicon wafer 110.

When the silicon oxide film is removed by the use of an apparatus of this type, the reaction product of the silicon oxide film with hydrofluoric acid escapes being gasified and persists as a residue on the surface of the silicon wafer.

In contrast, when a wet washing apparatus is utilized for removing the silicon oxide film on the surface of a silicon wafer, the silicon wafer 110 is sequentially immersed in an SC-1 solution, a dilute hydrofluoric acid (DHF), and water placed respectively in first through third liquid tanks 121-123 and then the wet silicon wafer 110 is placed in an IPA atmosphere until the surface thereof is dried as shown in FIG. 4.

When the silicon wafer 110 of a large diameter is placed in the hydrofluoric acid and is extracted later on from the acid, the etching of the silicon oxide film does not proceed uniformly because the lower part of the silicon wafer remains immersed in the hydrofluoric acid for the longest time as shown in FIG. 5A. Further, while the silicon wafer 110 is being pulled up from the liquid tank, the particles drifting on the surface of the hydrofluoric acid or water in the tank inevitably adhere to the surface of the silicon wafer as shown in FIG. 5B.

Among the sheet-fed type wafer washing apparatuses is counted another apparatus which operates by keeping a wafer mounted on a spinner and feeding a solution thereto from above. This apparatus inevitably compels the wafer to sustain a so-called watermark.

When a 6-inch wafer which had undergone the steps of drying shown in FIGS. 1A to 1D was examined for adhesion of particles to the surface, it was found to have some thousands of particles attached to the surface thereof. These particles originally departed from the surface of the wafer while the wafer was being washed, then drifted in the liquid, and ultimately adhered again to the wafer while the wafer was pulled up from the liquid. Some of these particles arise from the film on the wafer when the wafer is fabricated and others descend from the ambient air and land on the surface of the wafer. When the wafer is washed, they part from the wafer surface and mingle into the liquid in the liquid tank or adhere to the lateral wall of the liquid tank.

The IPA which mingles into the chemical liquid 103 held in the liquid tank 102 is indeed effective in exalting the surface tension of the chemical liquid and consequently preventing the particles from adhering again to the wafer. This effect, however, is not fully satisfactory.

Further, the sheet-fed type washing apparatus or washing method requires to solve such problems as repressing the infliction of watermark on the wafer and depriving the wafer of residue besides entailing the problem of adhesion of particles mentioned above.

### SUMMARY OF THE INVENTION

An object of this invention is to provide a method for the treatment of a substrate, which method is capable of allaying the adhesion of particles to the surface of a substrate which has undergone the treatment with a chemical solution and further, in the case of a sheet-fed operation, nullifying the infliction of watermark and the persistence of residue besides the adhesion of particles and an apparatus for the treatment of the substrate.

The first aspect of this invention concerns a process for washing and drying a substrate and comprises first washing the substrate with water and then pulling up the substrate into the atmosphere of inert gas and drying it therein.

According to this invention, since the oxygen gaining access to the surface of the substrate is only in a low concentration, the so-called watermark is no longer formed on the substrate.

The second aspect of this invention comprises placing a step of immersing a substrate in water and then pulling up the substrate from the water and again returning the substrate back into the water prior to the step of drying the surface of the substrate. According to this invention, the amount of particles on the surface of the substrate can be decreased by separating into the water the particles adhering to the surface of the substrate subsequent to the treatment with the chemical solution. Further by causing the water of an amount equivalent to the volume of the substrate and the substrate cassette to overflow the liquid tank when the substrate is returned into the water, most of the particles drifting near the surface of the water in the tank can be discharged from the liquid tank. As a result, the amount of particles suffered to adhere again to the surface of the substrate when the substrate is pulled up from the liquid tank is decreased.

Since the particles existing abundantly in the upper part of the water in the tank easily adhere by surface tension to the substrate, the decrease of the amount of particles existing in the upper part of the water in the tank is effective in curbing the adhesion of particles to the substrate.

While the substrate is temporarily pulled up from the water in the tank, the measure to have an inert gas contained in the environment in which the substrate is temporarily placed or keep the surface of the substrate constantly wetted with water in the atmosphere is effective in preventing surface of the substrate from being oxidized.

The third aspect of this invention comprises disposing in the lower part of the liquid tank a receptacle for receiving the liquid overflowing the liquid tank, electrically grounding the liquid tank, providing the liquid tank on the periphery thereof with a plurality of stepped liquid reservoirs, or adapting the liquid tank to hold water containing carbon oxides. According to this invention, the particles do not easily adhere to the liquid tank because the amount of the liquid flowing down the outer wall of the liquid tank decreases and the susceptibility of the liquid tank to electrification is consequently lowered, the ions in the liquid tank find easy way out of the liquid tank, and the amount of electric charge accumulated in the liquid tank decreases.

When the liquid is discharged from the liquid tank, therefore, the number of particles which remain in the liquid tank decreases. The number of particles to be contained in the liquid freshly placed in this liquid tank consequently decreases. As a result, the number of particles suffered to adhere to the wafer decreases.

The fourth aspect of this invention comprises disposing a substrate conveying means in a path for the conveyance of a substrate and further disposing a spin type wet chamber, a dry treating chamber, and a liquid tank chamber along the path for the conveyance of the substrate. According to this invention, by selecting two or more of the chambers as for removing the particles on the wafer in the spin type wet chamber or the liquid tank chamber, uniformizing the etching distribution of the oxide film, heightening the etching speed by the dry treatment, or performing the wet treatment and the drying simultaneously by the liquid tank chamber, the optimum treatment of removing the particles on the wafer, etching the film, washing the wafer, or drying the wafer can be selectively attained.

Further by having adjoined to the path for the conveyance of the substrate a buffer chamber capable of temporarily storing therein a wafer, the procedure of keeping one wafer in a waiting state in the buffer chamber and meanwhile treating another wafer in the spin type wet chamber, dry treatment chamber, or liquid tank chamber can be realized. Thus, within the apparatus for the treatment of a wafer, the treatments including the removal of particles, the etching of wafer, etc. can be carried out sequentially on a plurality of wafers.

By combining the wet treatment with the dry treatment, various treatments can be performed without inflicting watermark on the wafer surface.

### BRIEF DESCRIPTION OF THE DRAWINGS

FIGS. 1A to 1D are diagrams illustrating steps of drying subsequent to the wet treatment of the conventional semiconductor wafer;

FIG. 2 is a flow chart illustrating a step of drying subsequent to the wet treatment of the conventional semiconductor wafer;

FIG. 3 is a cross section illustrating one example of the conventional apparatus for dry washing a semiconductor wafer;

FIG. 4 is a cross section illustrating one example of the conventional apparatus for wet washing a semiconductor wafer;

FIG. 5A is a cross section illustrating the state of immersion of a semiconductor wafer in the conventional liquid tank;

FIG. 5B is a cross section illustrating the state of a semiconductor wafer being pulled up from the conventional liquid tank;

FIG. 6 is a schematic structural diagram of an apparatus for wet treatment of a semiconductor wafer (semiconductor substrate) to be used in the first embodiment of this invention;

FIGS. 7A to 7H are diagrams (part 1) illustrating a method for wet treatment of a semiconductor wafer as the first embodiment of this invention;

FIG. 8A is a flow chart (part 1) of the wet treatment of the semiconductor wafer as the first embodiment of this invention;

FIG. 8B is a flow chart (part 2) of the wet treatment of the semiconductor wafer as the first embodiment of this invention;

FIGS. 9A to 9D are cross sections illustrating an apparatus for carrying out the wet treatment of a semiconductor wafer according to the second embodiment of this invention;

FIG. 10 is a plan view illustrating the construction of an apparatus for the treatment of a wafer according to the third embodiment of this invention;

FIG. 11 is a cross section illustrating a first spin type wet chamber and the periphery in the apparatus for the treatment of a wafer as the third embodiment of this invention;

FIG. 12 is a cross section illustrating a second spin type wet chamber and the periphery of the apparatus for the treatment of a wafer as the third embodiment of this invention;

FIG. 13 is a cross section illustrating a dry treatment chamber and the periphery thereof in the apparatus for the treatment of a wafer as the third embodiment of this invention;

FIG. 14 is a cross section illustrating a liquid tank chamber and the periphery thereof in the apparatus for the treatment of a wafer as the third embodiment of this invention;

FIGS. 15A to 15D are cross sections illustrating a method for manufacturing a semiconductor device after treating a wafer as this invention; and

FIGS. 16A to 16D are cross sections illustrating the method for manufacturing the semiconductor device shown in FIG. 15C taken on line I-I as this invention.

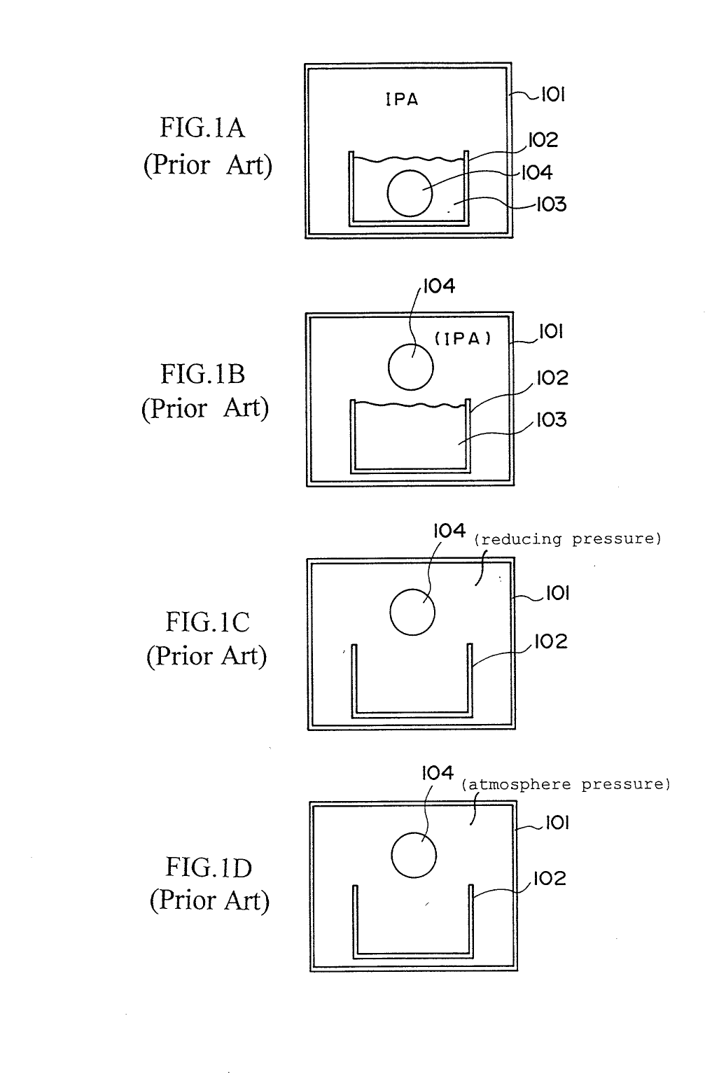

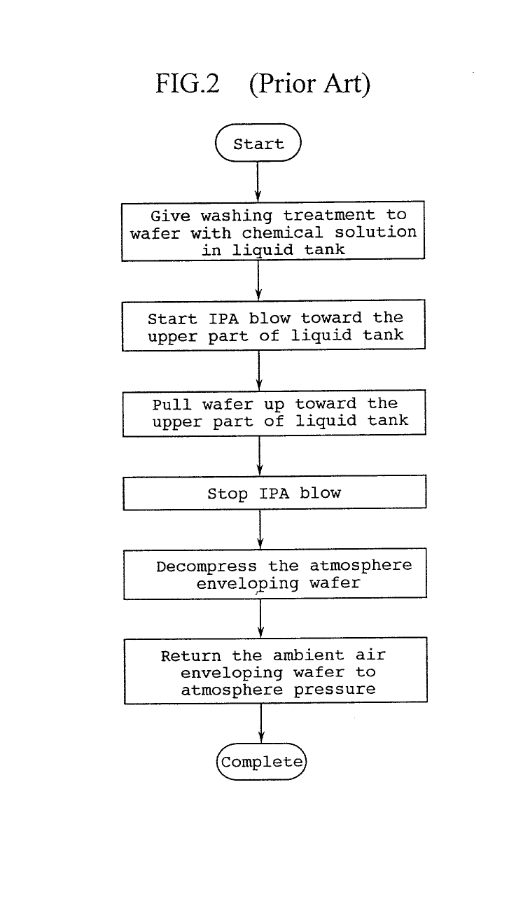

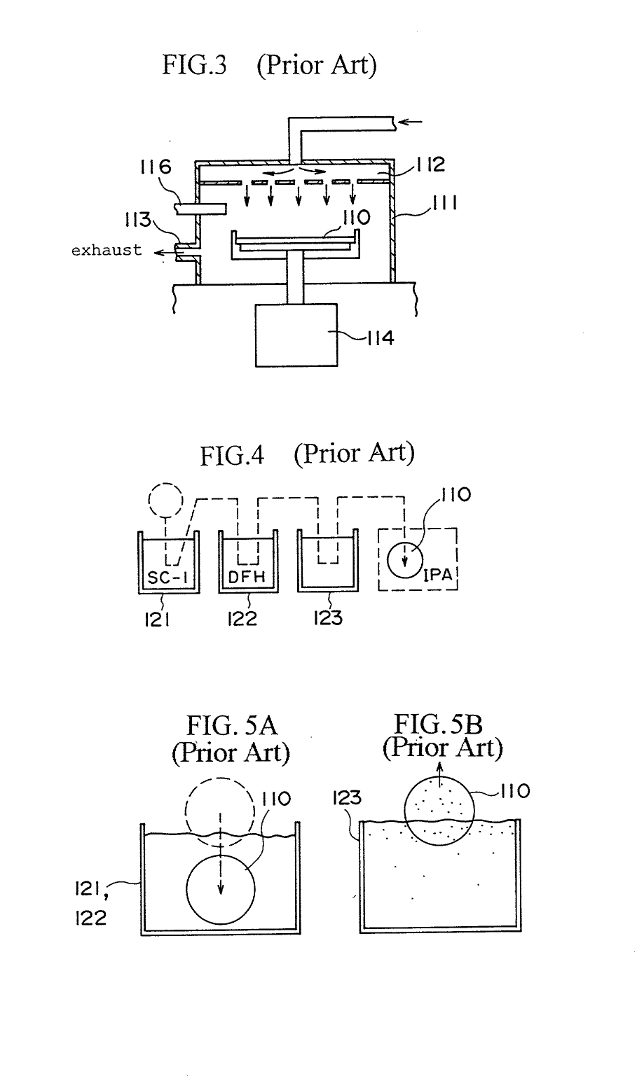

### DESCRIPTION OF THE PREFERRED EMBODIMENTS

Now, therefore, the preferred embodiments of this invention will be described below with reference to the drawings.

(First Embodiment)

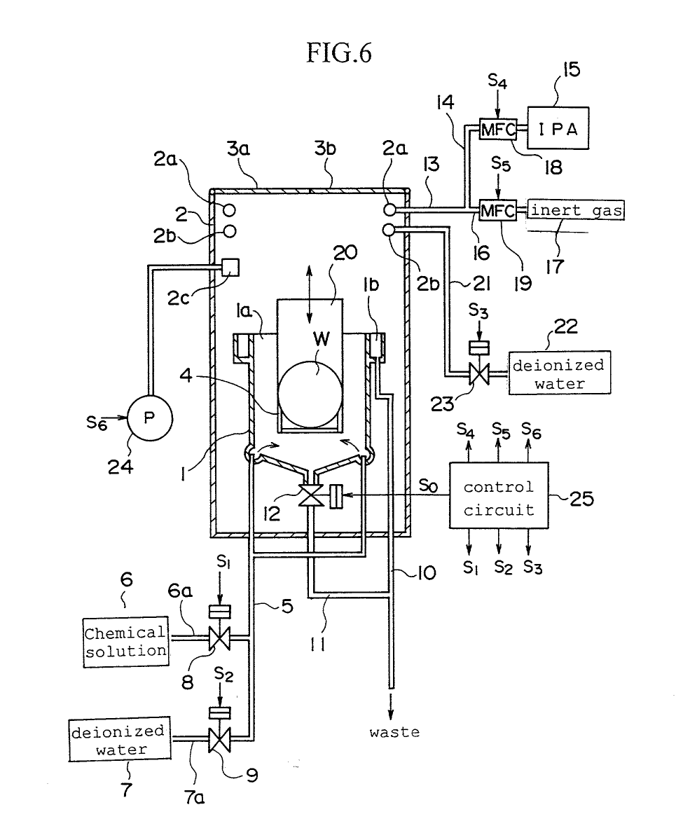

FIG. 6 is a cross section illustrating the first embodiment of the apparatus of this invention for washing a wafer.

In FIG. 6, freely openable covers 3a and 3b are attached to the upper openings in a chamber 2 for accommodating a liquid tank 1 which stores a chemical solution or deionized water.

The liquid tank 1 is formed of such a material as quartz, Teflon (tetrafluoroethylene resin), or vinyl chloride and it is provided in the upper part thereof with a large opening 1a for passing a wafer cassette 4. A first liquid inlet pipe 5 is connected to the bottom part of the liquid tank 1. This first liquid inlet pipe 5 is connected to a second liquid inlet pipe 6a drawn out of a chemical solution tank 6 and to a third liquid inlet pipe 7a drawn out of a deionized water tank 7. As concrete examples of the chemical solution in the chemical solution tank 6, hydrofluoric acid (HF) solution, a DHF (dilute HF) solution, an SC-1 solution composed of NH₄OH, H₂O₂, and H₂O, an SC-2 solution composed of HCl, H₂O₂, and H₂O, and an aqueous sulfuric acid solution composed of H₂SO₄ and H₂O may be cited.

A first switch valve 8 is attached to the second liquid inlet pipe 6a and a second switch valve 9 is attached to the third liquid inlet pipe 7a. By switching the first and second switch valves 8 and 9, the chemical solution in the chemical solution tank 6 and the deionized water in the deionized water tank 7 are selectively fed into the liquid tank 1. Liquid feed pumps not shown herein are severally connected to the second and third liquid inlet pipes 6a and 7a.

The liquid tank 1 is provided in the lateral part thereof with a liquid reservoir 1b for receiving the liquid overflowing the opening 1a of the liquid tank 1. To the bottom part of the liquid reservoir 1b is connected a first liquid outlet pipe 10 for extracting the liquid from the liquid reservoir 1b. A second liquid outlet pipe 11 is connected to the bottom part of the liquid tank 1 and a third switch valve 12 is attached to the second liquid outlet pipe 11.

In the empty space of the chamber 2 above the liquid tank 1, gas shower outlets 2a for blowing a gas and liquid shower outlets 2b for blowing deionized water are disposed.

To a first gas pipe 13 connected to the gas shower outlets 2a, an IPA tank 15 is connected via a second gas pipe 14. An inert gas cylinder 17 is connected via a third gas pipe 16 to the first gas pipe 13. Further, a first mass flow controller 18 is attached to the second gas pipe 14 and a second mass flow controller 19 is attached to the third gas pipe 16. By switching these first and second mass flow controllers 18 and 19, the inert gas in the IPA tank 15 and the nitrogen gas in the inert gas cylinder 17 are selectively fed through the gas shower outlet 2a into the liquid tank 1. The gas to be sealed in the inert gas cylinder 17 is nitrogen, argon, or the like. Nitrogen will be mentioned by way of example in the following description.

A deionized water tank 22 is connected via a liquid feed pipe 21 to the liquid shower outlet 2b and a fourth switch valve 23 is connected to the liquid feed pipe 21. The operation of the fourth switch valve 23 starts and stops the discharge of the shower of deionized water through the liquid shower outlet 2b. A compression pump (not shown) for accelerated supply of deionized water is attached to the deionized water tank 22.

The wafer cassette 4 is so constructed as to have a plurality of wafers W mounted thereon as spaced and is set on a lifter 20 so as to be raised or lowered and consequently dipped in the liquid held in the liquid tank 1 or pulled up from the liquid tank 1 or the chamber 2.

In the diagram, the reference numeral 2c designates a gas outlet of the chamber 2, the reference numeral 24 designates a gas discharge pump for decompressing the interior of the chamber 2 through the gas outlet 2c, and the reference numeral 25 designates a control circuit for adjusting the degrees of opening of the first through fourth switch valves 8, 9, 12, and 23 and the flow volumes in the mass flow controller 18 and 19.

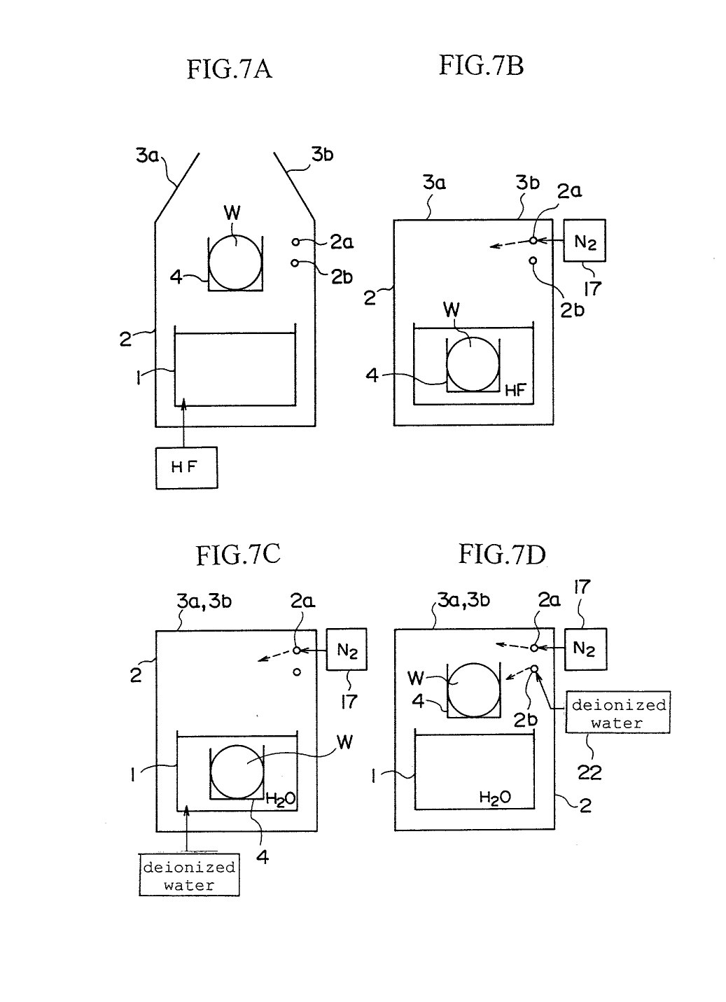

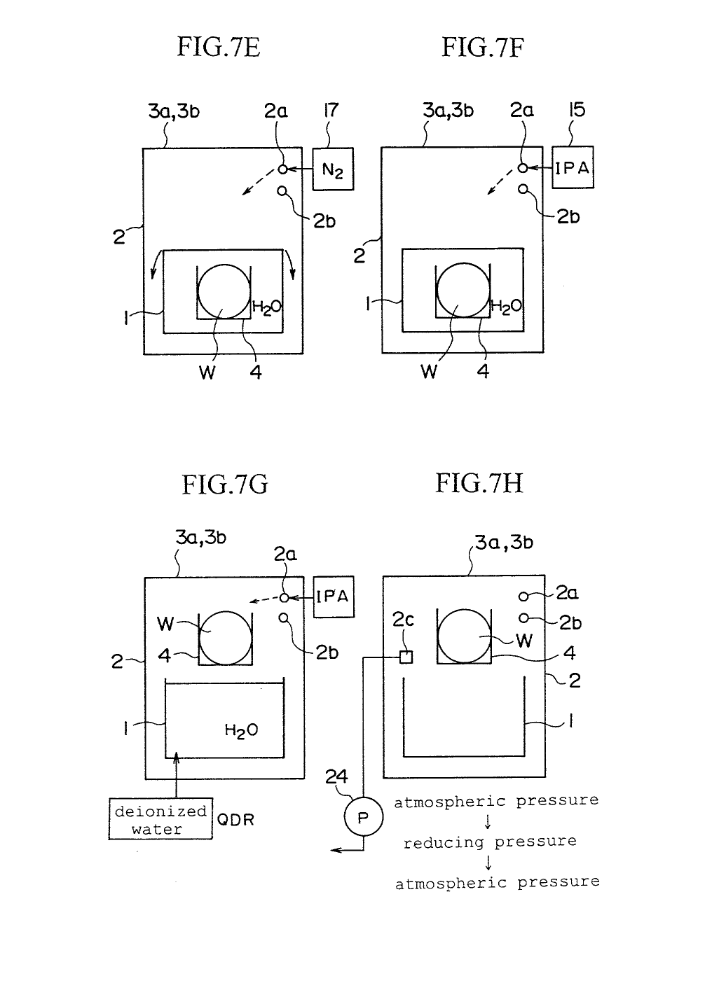

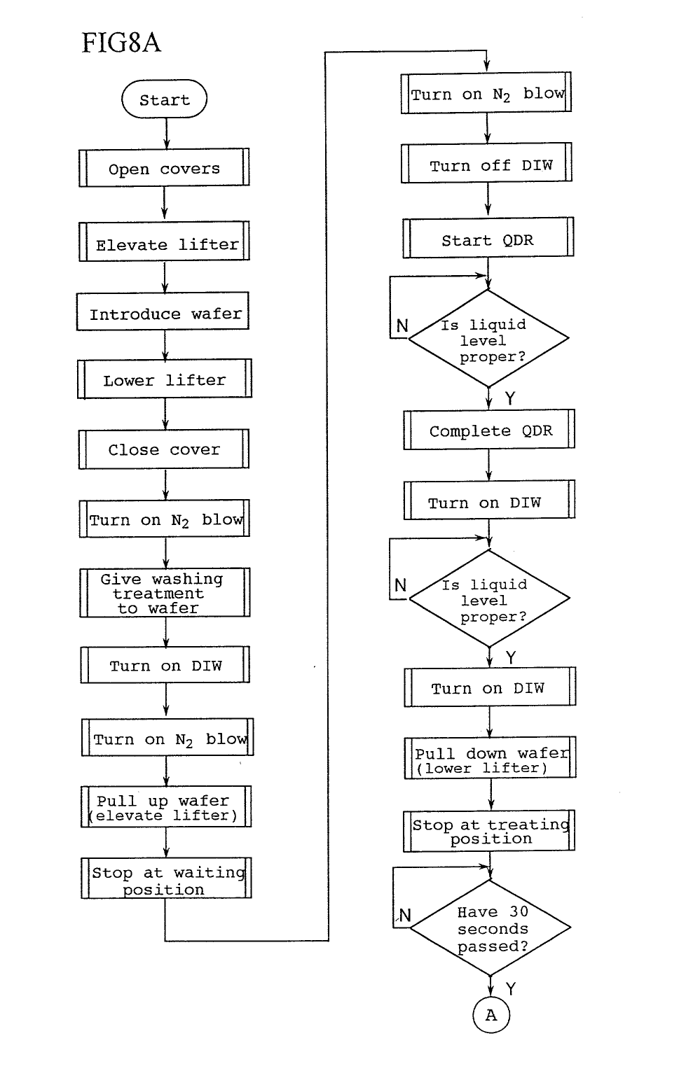

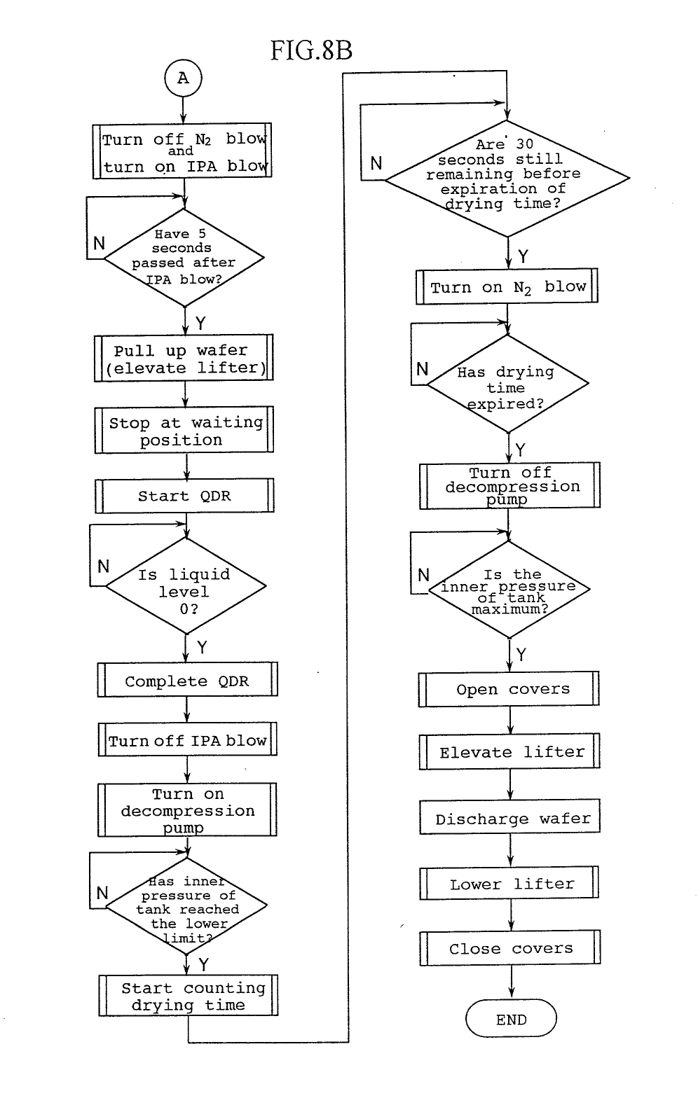

The process of washing the surface of a silicon wafer W by the use of the apparatus for washing a wafer which is constructed as described above will be described below with reference to FIGS. 7A to 7H, and 8A to 8B.

First, the covers 3a and 3b of the chamber 2 are opened as shown in FIG. 7A and the lifter 20 is elevated to a level above the liquid tank 1. Then, the wafer cassette 4 holding silicon wafers W is mounted on the lifter 20. Subsequently, the lifter 20 is lowered until the wafer cassette 4 is placed in the liquid tank 1. Then, the covers 3a and 3b are closed to seal tightly the interior of the chamber 2. To the interior of the liquid tank 1, hydrofluoric acid (HF) as the chemical solution has been preparatorily fed by opening the first switch valve 6a. The liquid tank 1, therefore, is now filled with hydrofluoric acid.

At substantially the same time that the lifter 20 is lowered, the nitrogen (N₂) gas is introduced through the gas shower outlet 2a into the chamber as illustrated in FIG. 7B by adjusting the valve of the second mass flow controller 19 to create a sparingly oxidizable atmosphere in the chamber 2.

When the silicon wafer W is introduced into the liquid tank 1, the silicon oxide film on the surface thereof is removed by the hydrofluoric acid and the particles p such as of silica adhering to the surface of the silicon oxide film are peeled from the silicon wafer W. The particles p are left drifting in the chemical solution held in the liquid tank 1. The washing of the surface of the silicon wafer W performed as described above embraces the process by the use of other chemical solution than hydrofluoric acid.

Then, when the treatment with the chemical solution is completed, the first switch valve 8 is closed and the second switch valve 9 is opened meanwhile to start the supply of deionized water to the liquid tank 1 as illustrated in FIG. 7C so as to switch the content of the liquid tank 1 from the chemical solution to the deionized water (DIW). During the switch of the two liquids, the silicon wafer W is kept placed in the liquid tank 1. Subsequently, the degree of opening of the valve of the second mass flow controller 19 is adjusted to stop the supply of the nitrogen gas to the chamber 2.

Thereafter, the wafer cassette 4 is pulled up from the liquid tank 1 and set in a waiting state at a prescribed position above the liquid tank 1 as illustrated in FIG. 7D by means of the lifter 20. In this while, the covers 3a and 3b of the chamber 2 remain in their closed state.

While the wafer cassette 4 is kept in the waiting state as described above, the nitrogen gas is blown through the gas shower outlet 2b against the silicon wafer W to prevent the surface of the wafer from oxidation. Where the occurrence of a natural oxide film on the surface of the silicon wafer W must be infallibly prevented, it is only necessary to project the column of deionized water from the liquid shower outlet 2a on the silicon wafer W and keep the surface of the silicon wafer W constantly in a wet state and prevent it from exposure to the air.

Next, the third switch valve 12 is opened to expel the deionized water in the liquid tank 1 by quick dump rinse (QDR) and remove the particles such as of silica remaining in the liquid tank 1 as much as possible. In this case, the deionized water is expelled through the liquid outlet pipe 11. When the deionized water consequently reaches a prescribed depth, the discharge of the deionized water is stopped and the interior of the liquid tank 1 is filled again with deionized water. Where the washing treatment must be expedited, the quick dump rinse may be omitted.

Then, the interior of the liquid tank 2 is filled with deionized water and the deionized water is left overflowing the liquid tank 2 as illustrated in FIG. 7E and the lifter 20 is lowered to immerse the silicon wafer W in the wafer cassette 4 in the deionized water held in the liquid tank 1. The deionized water which overflows the liquid tank 1 is collected in the liquid reservoir 1b and thence discharged via the first liquid outlet pipe 10. In this case, since the portion of the water held in the liquid tank which is equivalent to the total volume of the wafer cassette 4, silicon wafer W, and lifter 20 overflows the liquid tank, the particles are inevitably discharged together with the water from the liquid tank The following IPA blow treatment is performed after the elapse of 30 seconds, for example, from the time that the wafer cassette 4 is set at the prescribed position in the liquid tank 1. This IPA blow treatment is a treatment which is a familiar practice in the conventional technique.

First, the first and second mass flow controllers 18 and 19 are operated by the control circuit 25 to stop the supply of nitrogen gas through the gas shower outlet 2a. Then, the IPA is blown into the chamber 2 through the gas shower outlet 2a as illustrated in FIG. 7F.

After the elapse of a prescribed time such as, for example, 5 seconds after the blowing of IPA is started, the wafer cartridge 4 is pulled up from the liquid tank 1 and set at a waiting state at the prescribed position above the liquid tank 1 as illustrated in FIG. 7G. In this while, the covers 3a and 3b remain in their closed state.

When the IPA is blown against the silicon wafer W. the liquid on the surface of the silicon wafer W is gasified together with the IPA and the liquid on the surface decreases and the surface proportionately dries.

Then, the silicon wafer W is kept in the waiting state on the liquid tank 1 and the discharge of the waste liquid from the quick dump rinse is started to empty the liquid tank 1 of the liquid held therein. After the quick dump rinse is completed, the valve of the first mass flow controller 18 is closed to terminate the blowing of IPA.

Subsequently, the decompression pump 24 is set driving as illustrated in FIG. 7H to lower the interior of the chamber 2 below the atmospheric pressure and consequently accelerate the volatilization of the liquid on the surface of the silicon wafer W, with the resultant state retained for a stated period. The time for drying under a reduced pressure is set in advance. For the purpose of the drying, the interior of the chamber 2 is decompressed to about 80 mHg, for example.

Then, 30 seconds before the termination of the drying time, the second mass flow controller 19 is opened to resume the blowing of nitrogen through the gas shower outlet 2a into the chamber 2. When the drying time terminates, the decompression pump 24 is stopped to allow the interior of the chamber 2 to return to the atmospheric pressure.

This step completes the drying treatment.

Subsequently to the drying treatment, the covers 3a and 3b are opened and the lifter 20 is elevated to move the wafer cassette 4 out of the chamber 2. Then, the wafer cassette 4 is removed from the lifter 20 and the lifter 20 is lowered and the covers 3a and 3b of the chamber 1 are closed.

The closure of the covers 3a and 3b completes the step of wafer washing and the step of drying.

According to the present embodiment, the treatment for decreasing the amount of particles on the surface of the silicon wafer W is interposed between the treatment with the chemical solution and the treatment of drying as described above. To be specific, the silicon wafer W which has undergone the treatment with the chemical solution is pulled up from the liquid stank 1 and, in the ensuant state, is exposed to the forced current of nitrogen and consequently prevented from oxidation and, in the meantime, the liquid in the liquid tank is switched from the chemical solution to the deionized water and the deionized water is allowed to overflow the liquid tank. Thereafter, the wafer cassette 4 is returned to the liquid tank 1 and immersed in the deionized water therein. In this case, the number of particles drifting on the surface of the deionized water is decreased by causing the deionized water to overflow the liquid tank 1 and, at the same time, the number of particles on the surface of the deionized water in the liquid tank is further decreased by causing the portion of the deionized water existing in the upper part of the interior of the liquid tank 1 to overflow the liquid tank 1 in consequence of the immersion of the wafer cassette 4 into the deionized water.

The fact that the number of particles on the surface of the deionized water in the liquid tank 1 is decreased as described above results in decreasing the amount of particles suffered to adhere to the silicon wafer W by surface tension. Further, by blowing nitrogen gas against the silicon wafer W, not only the surface of the silicon wafer W is prevented from oxidation but also the silicon wafer W is kept in an inactive state which discourages adhesion of particles thereto.

The following test was performed for evaluating the steps mentioned above.

First, three silicon wafers W having a silicon oxide film formed thereon were prepared. Then, the silicon wafers W were immersed in a hydrofluoric acid solution under the conditions that the silicon oxide films thereon would be etched to a depth of 200 Å. After the treatment with the hydrofluoric acid solution, the liquid in the liquid tank was switched from the hydrofluoric acid solution to deionized water. The silicon wafers W were immersed for 15 minutes in the deionized water. Subsequently, the wafer cartridge 4 was pulled up from the liquid tank 1 and then the silicon wafers W were again immersed in the deionized water for 30 seconds and they were pulled up and blown with IPA at 50° C. to be dried. As the result, the numbers of particles on the surfaces of these three silicon wafers W were found to be 210, 228, and 292.

In contrast, the conventional procedure which comprised removing the oxide film on the surface of a silicon wafer with hydrofluoric acid, immersing the silicon wafer in deionized water for 15 minutes, and thereafter pulling the silicon wafer up from the deionized water and exposing the surface thereof to the forced current of IPA at 50° C. thereby drying the surface was performed on three silicon wafers. As a result, the numbers of particles on the surfaces of the silicon wafers were found to be 2443, 1809, and 1262.

Thus, the present embodiment produced a prominent effect in curbing the adhesion of particles to the surface of a wafer.

In the test, the silicon wafers had a diameter of 6 inches and they were raised and lowered at a fixed speed of 4 mm/sec.

(Second Embodiment)

The first embodiment is directed to a method for rendering difficult the adhesion of particles on the surface of a chemical solution or deionized water to a wafer. In contrast, the present embodiment is directed to a method for preventing particles from adhering to the inner wall of the liquid tank 1 and curbing the entry of these particles into a liquid freshly fed in the liquid tank 1.

The adhesion of particles to the inner wall of the liquid tank 1 is caused by the electrification of the liquid tank 1 which is generated by the friction between the liquid tank 1 and the liquid held therein. This electrification causes the particles to adhere to the inner wall of the liquid tank 1 and renders difficult the discharge of particles from within the liquid tank 1.

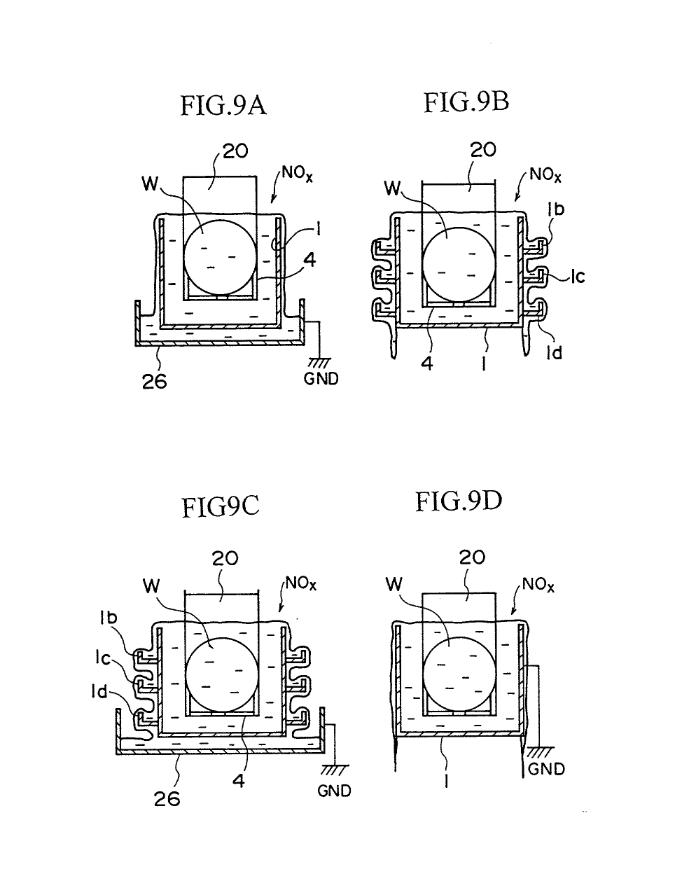

The present embodiment, therefore, adopts an apparatus constructed as illustrated in FIGS. 9A to 9D for preventing this electrification.

First, the construction illustrated in FIG. 9A has a liquid receptacle 26 disposed below the liquid tank inside the chamber 2 and has this liquid receptacle 26 electrically grounded. In this apparatus, even when the liquid (deionized water or chemical solution) overflowing the liquid tank generates friction with the liquid tank 1 and negatively charges the liquid tank 1, for example, the liquid tank 1 and the liquid tend to resume neutrality electrostatically through the medium of the overflowing liquid and the liquid receptacle 26. As a result, the electrification of the liquid tank 1 is repressed and the number of particles adhering to the inner wall of the liquid tank 1 is decreased. It is provided, however, that the liquid overflowing the liquid tank 1 is required to have the flow volume thereof controlled so that it may continue into the liquid in the liquid receptacle 26.

The construction shown in FIG. 9B has a plurality of stepped liquid reservoirs 1b, 1c, and id attached to the outer wall of the liquid tank 1 for the purpose of decreasing the amount of water contacting the outer side of the liquid tank 1 and consequently repressing the friction between the lateral side of the liquid tank 1 and the liquid. Further, part of the liquid overflowing the liquid reservoirs 1b, 1c, and 1d falls down without contacting the lateral wall of the liquid tank 1 and the liquid reservoirs serve the purpose of lowering the flow rate of the liquid on the lateral wall of the liquid tank 1. As a result, the amount of electrification of the liquid tank 1 is decreased.

The construction illustrated in FIG. 9C combines the constructions of FIG. 9A and FIG. 9B and manifests an increased effect in decreasing the electrification of the liquid tank 1.

The construction illustrated in FIG. 9D has the liquid tank 1 electrically grounded. As a result, the minus ions in the liquid tank 1 easily escape to the exterior from the liquid tank 1 and the particles adhere to the inner wall of the liquid tank 1 only with increased difficulty.

When the liquid to be placed in the liquid tank 1 happens to be ionized water, the conversion of the deionized water into positive ions can be prevented by increasing the resistance of the deionized water. When the deionized water has carbon dioxide gas dissolved therein for the purpose of exalting the resistance thereof, the ionization of the liquid tank 1 is also prevented. In an experiment, the adoption of the construction and the method described above has resulted in lowering the number of particles on a wafer, 6 inches in diameter, to the mark of 1000. In contrast, the adoption of the conventional construction and method has resulted in lowering the number of particles on a wafer to the mark of 2000.

(Third Embodiment)

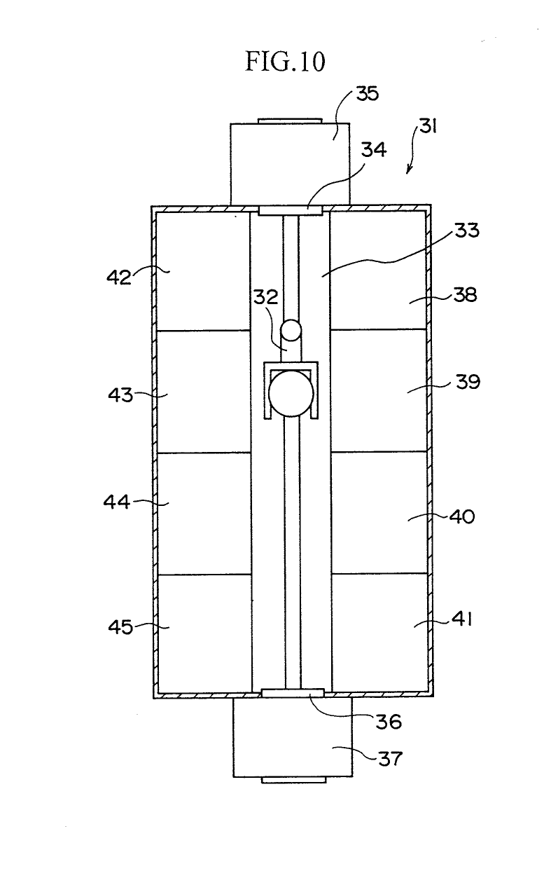

FIG. 10 is a plan view illustrating the construction of a sheet-fed type apparatus for the treatment of a wafer to be used in the process for the production of a semiconductor device.

A sheet-fed type apparatus 31 for the treatment of a wafer illustrated in FIG. 10 is provided with a vacuum conveyor chamber 33, to the inferior of which a wafer conveying robot 32 is fitted. The wafer conveying robot 32 is possessed of a structure for mounting a wafer W, a structure for nipping the wafer W in the direction of the diameter thereof, and a structure capable of selectively turning the direction of the wafer W laterally and longitudinally.

To the wafer inlet side of the vacuum conveyor chamber 33, a loading chamber 35 is attached through the medium of a first gate 34. To the wafer outlet side thereof, an unloading chamber 37 is attached through the medium of a second gate 36.

Along one side of the vacuum conveyor chamber 33, first through fourth buffer chambers 38, 39, 40, and 41 for temporary storage of wafers W are arranged sequentially in the direction of wafer conveyance. In the buffer chambers 38-41, wafers are kept waiting for the next treatments. Along the other side of the vacuum conveyor chamber 33, a first spin type wet treating chamber 42, a second spin type wet treating chamber 43, a dry washing chamber 44, and a liquid tank chamber 45 are arranged sequentially in the direction of wafer conveyance. The interiors of the first through fourth buffer chambers 38, 39, 40, and 41 and the interior of the vacuum conveyor chamber 33 are exposed to an inert atmosphere of nitrogen, argon, etc.

When an arbitrary plurality of chambers are selected from among the first spin type wet treating chamber 42, the second spin type wet treating chamber 43, the dry washing chamber 44, and the liquid tank chamber 45 are selected and used for the treatment, the wafers can be successively treated in the chambers and the treatment of a plurality of wafers can be carried out smoothly by keeping the wafers W waiting in the relevant adjoining chambers 38-41.

Now, the constructions of the first spin type wet treating chamber 42, the second spin type wet treating chamber 43, the dry washing chamber 44, and the liquid tank chamber 45 and the examples of their uses will be described below.

(1) First Spin Type Wet Chamber

The first spin type wet chamber 42, as illustrated in FIG. 11, is provided with a spinner 42b possessed of a wafer mounting plate 42a and a third gate 42c disposed on the boundary with the vacuum conveyor chamber 32. To the interior of the first spin type wet chamber 42, a gas feed nozzle 42d and a liquid feed nozzle 42e are fitted. The liquid feed nozzle 42d is joined to a liquid feeding part 42f for feeding at least one of the SC-1 solution, the hydrofluoric acid (HF) solution, and the deionized water (H₂O). Then, to the gas feed nozzle 42d, an alcohol feeding part 42g for feeding the IPA is connected.

In FIG. 11, the reference numeral 38a designates a fourth gate which is disposed on the boundary between the vacuum conveyor chamber 33 and the first buffer chamber 3.

The following operation is carried out when the particles on the silicon wafer W are removed by the use of the first spin type wet chamber 42 constructed as described above.

First, with the silicon wafer W kept as mounted on the wafer mounting plate 42a, the wafer mounting plate 42a is set rotating. When the SC-1 solution is fed subsequently from the liquid feed nozzle 42d to the silicon wafer W for about 10 minutes, the particles are removed together with the natural oxide film of the surface.

Then, after the supply of the SC-1 solution is stopped, the deionized water is fed through the liquid feed nozzle 42d to wash the surface of the silicon wafer W. Thereafter, the supply of the deionized water is stopped and the surface of the silicon wafer W is dried by feeding the IPA through the gas feed nozzle and rotating the wafer mounting plate 42a.

As a result, the removal of the particles on the silicon wafer W is completed, the third gate is opened, and the silicon wafer W is conveyed by the robot 32 to the first buffer chamber 38 and put to temporary storage therein.

Optionally, the chemical solution may be supplied to the silicon wafer W while the surface of the silicon wafer W is rubbed with a brush of nylon or PVA. Alternatively, the supply of the chemical solution to the silicon wafer W may be continued while the silicon wafer W is vibrated by the use of a megasonic. As a result, the removal of the particles is efficiently carried out.

(2) Second Spin Type Wet Chamber

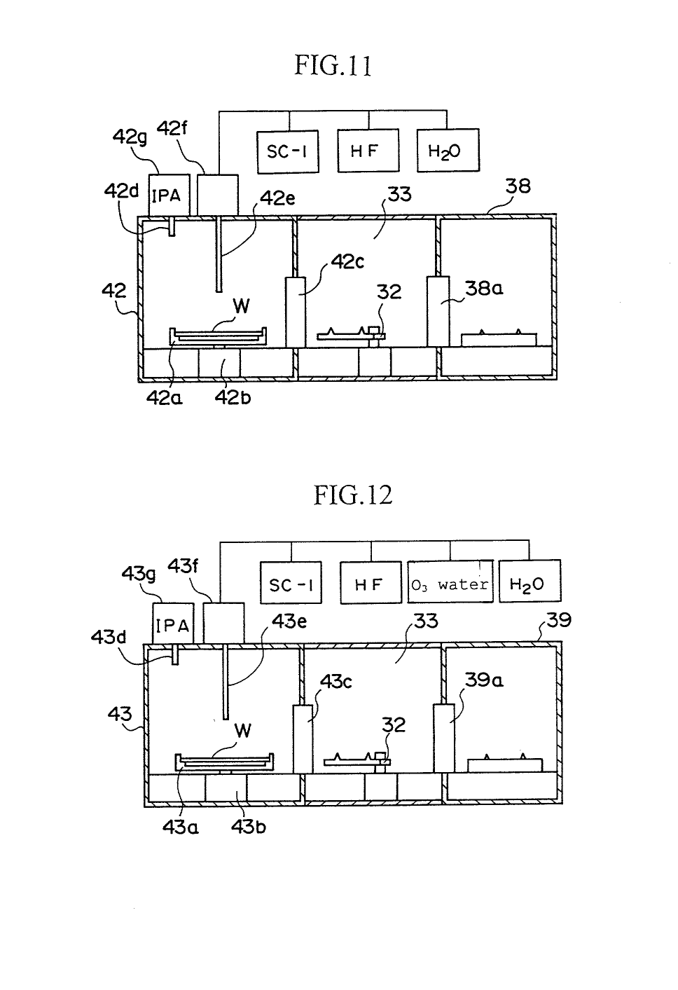

The second spin type wet chamber 43, as illustrated in FIG. 12, is provided with a spinner 43b possessed of a wafer mounting plate 43a and a fifth gate 43c disposed on the boundary with the vacuum conveyor chamber 33. To the interior of the second spin type wet chamber 43, a gas feed nozzle 43d and a liquid feed nozzle 43e are fitted. The liquid feed nozzle 43e is connected to a liquid feed part 43f for feeding at least one of the SC-1 solution, the hydrofluoric acid (HF) solution, the ozone (O₃), and the aqueous hydrogen peroxide solution (H₂O₂). To the gas feed nozzle 43d, an alcohol feed part 43g for supplying the IPA is connected.

In FIG. 12, the reference numeral 39a designates a sixth gate disposed on the boundary between the vacuum conveyor chamber 33 and the second buffer chamber 39.

The following operation is carried out when the silicon oxide film on the silicon wafer W is removed in a thickness of about 40 nm by the use of the second spin type wet chamber 43 constructed as described above.

First, with the silicon wafer W kept as mounted on the wafer mounting plate 43a, the wafer mounting plate 43a is rotated. When the hydrofluoric acid (HF) solution or the mixed solution of hydrofluoric acid and the aqueous hydrogen peroxide solution is subsequently fed through the liquid feed nozzle 43d to the silicon wafer W for about 15 minutes, the silicon oxide film on the surface of the silicon wafer W is removed.

When the supply of the hydrofluoric acid is stopped, the water containing ozone (hereinafter referred to as “ozone water”) is fed through the liquid feed nozzle 43d to wash the surface of the silicon wafer W with the water. Thereafter, the supply of the ozone water is stopped and the surface of the silicon wafer W is dried by feeding the IPA through the gas feed nozzle 43d to the wafer mounting plate 43a and meanwhile rotating the wafer mounting plate 43a. As a result, the removal of the silicon oxide film on the silicon wafer W is completed.

Incidentally, the ozone water is fed to the surface of the silicon wafer W before this surface is dried for the purpose of imparting hydrophilicity to the surface of the silicon wafer W and preventing the surface from sustaining watermark.

As a result, the etching of the oxide film on the silicon wafer W is completed, the fifth and sixth gages 43c and 39a are opened, the silicon wafer W is conveyed by the robot 32 to the second buffer chamber 39, and put to temporary storage therein.

(3) Dry Treating Chamber

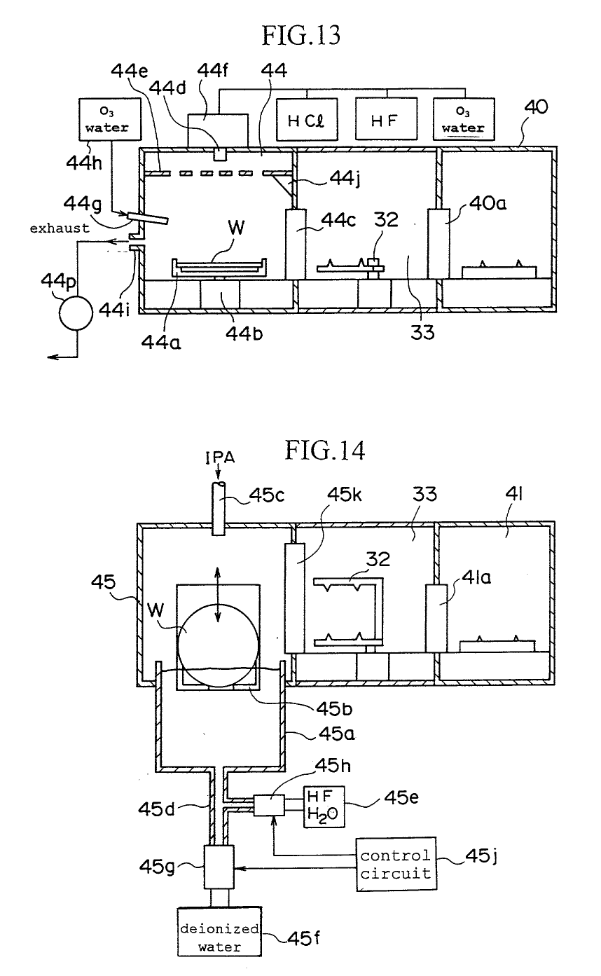

The dry treating chamber 44, as illustrated in FIG. 13, is provided with a wafer mounting plate 44a, a motor 44b for rotating the wafer mounting plate 44a, and a seventh gate 44c disposed on the boundary with the vacuum conveyor chamber 33. To the upper part inside the dry treating chamber 44, a gas feed nozzle 44d is fitted. A shower plate 44e possessed of numerous pores is disposed in the empty space between the gas feed nozzle 44d and the wafer mounting plate 44a. This shower plate 44e fulfills the function of diffusing the gas fed through the gas feed nozzle 44d and supplying the diffused gas uniformly to the wafer W. The gas feed nozzle 44d is connected to a gas feed part 44f and adapted to feed the gaseous hydrochloric acid (HCl), hydrofluoric acid (HF) solution, or the ozone (O₃) which has been selected to the gas feed part 44f.

To the lateral part of the dry treating chamber 44, a liquid feed nozzle 44g is fitted. To this liquid feed nozzle 44g, a liquid feed part 44h for supplying water (H₂O) is connected.

Further, the dry treating chamber 44 has an ultraviolet light source 44j fitted to the interior thereof and it is adapted to project a beam of ultraviolet light on the wafer W on the wafer mounting plate 44a.

In FIG. 13, the reference numeral 44i designates a gas outlet formed in the dry treating chamber 44, the reference numeral 44p designates a decompression pump connected to the gas outlet 44i, and the reference numeral 40a designates an eighth gate disposed on the boundary between the vacuum conveyor chamber 33 and the second buffer chamber 40.

The following operation is carried out when the silicon oxide film on the silicon wafer W is removed in a thickness of about 500 nm by the use of the dry treating chamber 44 which is constructed as described above.

First, with the silicon wafer W kept as mounted on the wafer mounting plate 44a, the ultraviolet light is projected on the silicon wafer W and the ozone water is supplied through the liquid feed nozzle 44g to the surface of the silicon wafer W to wash the surface and remove the particles. Subsequently, the silicon oxide film on the silicon wafer W is removed by supplying the hydrochloric acid gas through the gas feed nozzle 44d to the silicon wafer W for several minutes and, at the same time, projecting the ultraviolet light on the silicon wafer W. In the present apparatus, the etching speed of the silicon oxide film is high as compared with the treatment in the first and second spin type wet chambers.

Then, after the supply of the hydrochloric acid gas is stopped, the pressure inside the dry treating chamber 44 is lowered below the atmospheric pressure, the seventh and eighth gates 44c and 40a are opened, and the silicon wafer W is conveyed by the robot 32 to the third buffer chamber 40 and put to temporary storage therein.

Incidentally, the vapor of hydrofluoric acid may be used in the place of the hydrochloric acid gas for the purpose of etching the silicon oxide film. The removal of the particles on the surface of the silicon wafer W cannot be attained by the use of the vapor of hydrofluoric acid. In this case, therefore, after the etching of the silicon oxide film is completed, the ozone water is supplied through the liquid feed nozzle 44g to the surface of the silicon wafer W to wash the surface. After the supply of the ozone water is completed, the wafer mounting plate 44a is rotated to effect spin drying.

As a result, the etching of the oxide film on the silicon wafer W is completed.

(4) Liquid Tank Chamber

The liquid tank chamber 45, as illustrated in FIG. 14, is provided with a one-bath type liquid tank 45a, a wafer cassette 45b, and an IPA feed inlet 45c. The liquid tank 45a has a size enough for accommodating the wafer cassette 45b containing just one wafer, 8 inches or 12 inches in diameter, for example. A liquid feed pipe 45d is connected to the bottom part of the liquid tank 45a. The liquid feed pipe 45d is connected to a chemical solution tank 45e or a deionized water tank 45f through the medium of switch valves 45g and 45h. A control circuit 45j is adapted to operate the switch valves 45g and 45h so as to feed selectively the chemical solution in the chemical solution tank 45e and the deionized water in the deionized water tank 45f to the liquid tank 45a. The chemical solution, for example, is hydrofluoric acid or the mixed solution of hydrofluoric acid with an aqueous hydrogen peroxide solution.

In FIG. 14, the reference numeral 45k designates a ninth gate disposed on the boundary between the liquid feed chamber 45 and the vacuum conveyor chamber 33 and the reference numeral 41a designates a tenth gate disposed on the boundary between the vacuum conveyor chamber 33 and the fourth buffer chamber 41.

The following operation is carried out when the silicon oxide film on the surface of the silicon wafer W is removed in a thickness of about 20 nm by the use of the liquid tank chamber 45 which is constructed as described above.

First, the wafer conveying robot 32 in the vacuum conveyor chamber 33 nips diametrically the silicon wafer W held in one of the first through third buffer chambers 38-40 and conveys the silicon wafer W to the front of the liquid tank chamber 45. Thereafter, the wafer conveying robot 32 erects the silicon wafer W into the upright state and inserts it into the wafer cassette 45b. Then, in the liquid tank 45a, the silicon oxide film on the surface of the silicon wafer W is etched with the mixed solution or the hydrofluoric acid solution for a period in the range of 10-15 minutes.

Then, the two switch valves 45g and 45h are so manipulated as to stop the supply of the chemical solution to the liquid tank 45a and, at the same time, start the supply of the deionized water to the liquid tank 45a. In this case, the chemical solution is allowed to overflow the liquid tank 45a.

After the washing of the silicon wafer W with the deionized water is completed, the IPA in the gaseous state is introduced through the IPA feed inlet 45c into the atmosphere enveloped with the liquid tank chamber 45.

Next, the wafer cassette 45b is pulled up to expose the silicon wafer W to the IPA environment and consequently effect the drying of the liquid on the surface of the silicon wafer W. As a result, the etching of the oxide film on the silicon wafer W is completed. The ninth and tenth gates 45k and 41a are opened and the silicon wafer W is conveyed by the wafer conveying robot 32 to the fourth buffer chamber 41 and put to temporary storage therein.

As is clear from the description given in (1)-(4) above, while the etching of the silicon oxide film is attainable in the second spin type wet treating chamber 43, the dry treating chamber 44, and the liquid tank chamber 45 alike, these chambers have proper amounts of etching and proper degrees of uniformity of etching of their own. For example, the second spin type wet treating chamber 43 and the liquid tank chamber 45 have good uniformity of etching and the dry treating chamber 44 has inferior uniformity as compared therewith.

For the second spin type wet treating chamber 43, the dry treating chamber 44, and the liquid tank chamber 45, the adequate amounts of etching of the silicon oxide film are not more than 100 nm, not more than 500 nm, and not more than 20 nm in thickness respectively.

Next, the step of removing by etching the silicon oxide film on the surface of the silicon wafer W by the use of the sheet-fed type apparatus 31 for the treatment of a wafer mentioned above will be described below with reference to examples.

### FIRST EXAMPLE

The following step is adopted where the thickness of the SiO₂ film on the silicon wafer W is about 10 nm and the demand for uniformity of etching is strict. Hydrofluoric acid is used as the final chemical solution.

First, in the first spin type wet treating chamber 42, the particles on the surface of the silicon wafer W are removed by the use of the SC-1 solution in accordance with the procedure shown in the item (1) above. Thereafter, the silicon wafer W is placed for temporary storage in the first buffer chamber 38 and further set in place in the wafer cassette 45b of the liquid tank chamber 45 by the use of the wafer conveying robot 32.

In the liquid tank chamber 45, the silicon oxide film is removed from the surface of the silicon wafer W by the use of the hydrofluoric acid solution as the chemical solution in accordance with the procedure shown in (4) above. Thereafter, the silicon wafer W is conveyed from the liquid tank chamber 45 to the fourth buffer chamber 41, placed for temporary storage therein, and then pulled out into the unloading chamber 37 after the second gate has been opened by the wafer conveying robot 32.

### SECOND EXAMPLE

The following step is adopted where the SiO₂ film of a thickness of about 40 nm is formed on the silicon wafer W and the demand for uniformity of etching is strict. In this case, hydrofluoric acid is used as the final chemical solution.

First, in the first spin type wet treating chamber 42, the particles are removed from the surface of the silicon wafer W by the use of the SC-1 solution in accordance with the procedure shown in (1) above.

Then, the silicon wafer W is moved from the first spin type wet treating chamber 42 to the first buffer chamber 38, placed for temporary storage in the first buffer chamber 38, and thereafter mounted on the wafer mounting plate 43a of the second spin type wet treating chamber 43 by the use of the wafer conveying robot 32.

In the second spin type wet treating chamber 43, the treatment is performed at a relatively high etching speed and in such a manner as to avoid infliction of watermark. In the second spin type wet treating chamber 43, the silicon oxide film is etched in a thickness of only 40 cm by using hydrofluoric acid as the chemical solution and the ozone water for the washing in accordance with the procedure shown in (2) above.

Subsequently, for the purpose of removing the natural oxide film remaining on the silicon wafer W, the silicon wafer W is placed in the wafer cassette 45b of the liquid tank chamber 45 by means of the wafer conveying robot 32. The liquid tank chamber 45 is put to use.

In the liquid tank chamber 45, the natural oxide film is removed from the surface of the silicon wafer W by using the hydrofluoric acid solution as the chemical solution in accordance with the procedure shown in (4) above. Thereafter, the silicon wafer W is conveyed from the liquid tank chamber 45 to the fourth buffer chamber 41, placed for temporary storage therein, and thereafter pulled out into the unloading chamber 37 after the second gate has been opened.

### THIRD EXAMPLE

The following step is adopted where the SiO₂ film formed on the silicon wafer W has a thickness of about 200 nm and the uniformity of etching does not matter. In this case, hydrofluoric acid is not required to be used as the final chemical solution.

First, in the first spin type wet treating chamber 42, the particles are removed from the surface of the silicon wafer W by using the SC-1 solution in accordance with the procedure shown in (1) above.

Then, the silicon wafer W is moved from the first spin type wet treating chamber 42 to the first buffer chamber 38, placed for temporary storage therein, and thereafter mounted on the wafer mounting plate 44a of the dry treating chamber 44 by the use of the wafer conveying robot 32.

In the dry treating chamber 44, the treatment is performed at a high etching speed in such a manner as to avoid inflicting watermark. In the dry treating chamber 44, the silicon oxide film is etched in a thickness of only 40 nm by using hydrofluoric acid as the chemical solution and the ozone water for the washing in accordance with the procedure shown in (3) above.

Subsequently, for the purpose of removing the natural oxide film remaining on the silicon wafer w, the silicon wafer W is placed in the wafer cassette 45b of the liquid tank chamber 45 by the use of the wafer conveying robot 32. The liquid tank chamber 45 is put to use.

In the liquid tank chamber 45, the natural oxide film is removed from the surface of the silicon wafer W by using the hydrofluoric acid solution as the chemical solution in accordance with the procedure shown in (4) above. Thereafter, the silicon wafer W is conveyed from the liquid tank chamber 45 to the fourth buffer chamber 41, placed for temporary storage therein, and thereafter pulled out into the unloading chamber 37 after the second gate has been opened.

### FOURTH EXAMPLE

The following step is adopted where the SiO₂ film having a thickness of about 40 nm is formed on the silicon wafer W and the demand for uniformity of etching is strict. In this case, hydrofluoric acid is not used as the final chemical solution.

First, in the first spin type wet treating chamber 42, the particles are removed from the surface of the silicon wafer W by using the SC-1 solution in accordance with the procedure shown in (1) above.

Then, the silicon wafer W is moved from the first spin type wet treating chamber 42 to the first buffer changer 38, placed for temporary storage therein, and thereafter mounted on the wafer mounting plate 43a of the second spin type wet treating chamber 43 by the use of the wafer conveying robot 32.

In the second spin type wet treating chamber 43, the treatment is performed at a relatively high etching speed in such a manner as to avoid inflicting watermark. In the second spin type wet treating chamber 43, the silicon oxide film is etched in a thickness of only 40 nm by using hydrofluoric acid as the chemical solution and the ozone water for the washing in accordance with the procedure shown in (2) above.

Thereafter, the silicon wafer W is conveyed from the second spin type wet treating chamber 43 to the second buffer chamber 39, placed for temporary storage therein, and thereafter pulled out into the unloading chamber 37 after the second gate has been opened.

### FIFTH EXAMPLE

The following step is adopted where the removal of particles on the silicon wafer W is the sole object.

First, in the first spin type wet treating chamber 42, the particles are removed from the surface of the silicon wafer W by using the SC-1 solution in accordance with the procedure shown in (1) above.

Thereafter, the silicon wafer W is temporarily placed in the first buffer chamber 38, then conveyed from the first spin type wet treating chamber 41 to the first buffer chamber 38, placed for temporary storage therein, and subsequently pulled out into the unloading chamber 37 after the second gate has been opened.

Incidentally, in all the embodiments described above, since the silicon wafer and the semiconductor wafer are invariably destined to serve as a substrate for the formation of a semiconductor element, the words “silicon substrate” and “semiconductor substrate” used therein have the same meaning.

The substrate as the object for the treatment with the chemical solution and the washing is contemplated herein in a broad sense to embrace not only the semiconductor substrate but also the exposure mask grade substrate and the thin-film transistor (TFT) substrate.

Next, with the use of the semiconductor substrate (semiconductor wafer) which is subjected to the above cleaning process or chemical process, steps of forming an EEPROM cell on the semiconductor substrate will be explained in brief hereunder.

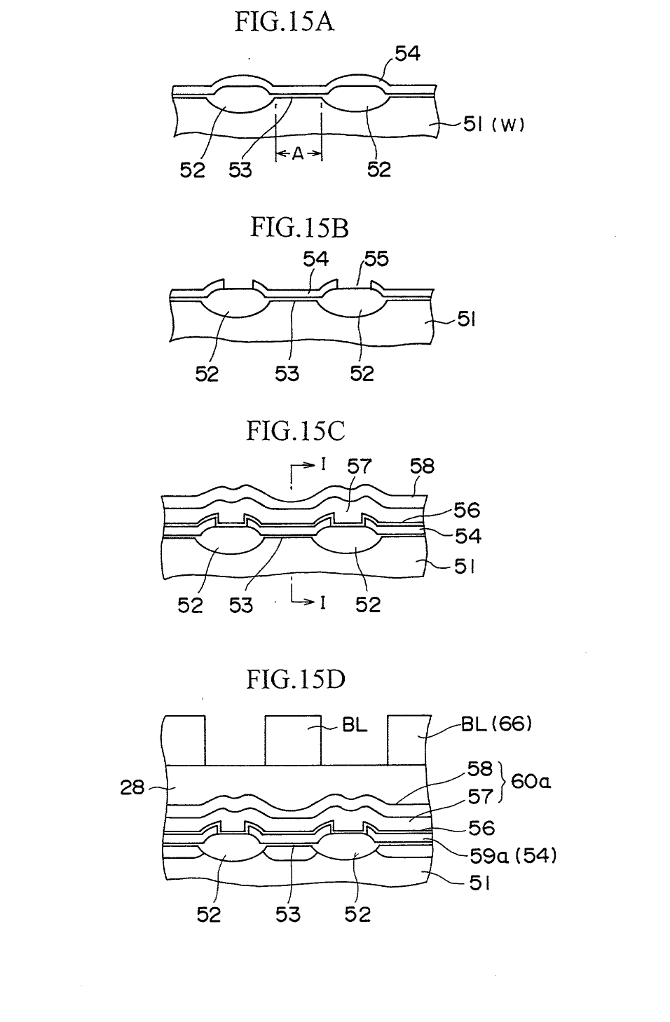

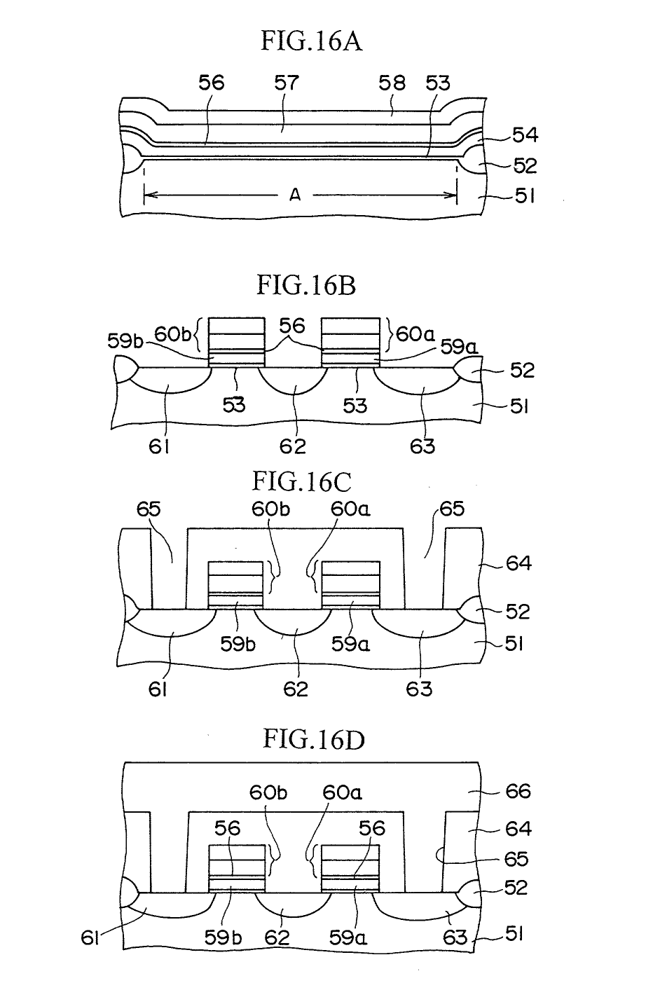

FIGS. 15A to 15D show respectively a sectional shape of the EEPROM cell along the word line, and FIGS. 16A to 16D are sectional views which are viewed from a line I-I in FIG. 15C and show respectively a sectional shape along bit line.

At first, as shown in FIG. 15A, a field oxide layer 52 is grown on the surface of the silicon substrate 51 by selective oxidation by use of a mask (not shown) made of silicon nitride, and then the mask is removed.

Subsequently, a tunnel oxide film 53 made of SiO2 is formed by thermally oxidizing the region A surrounded by the field oxide layer 52 at 1050° C. to have a thickness of 10 nm. Thereafter, a first phosphorus (impurity)doped amorphous silicon layer 54 is grown on the tunnel oxide film 53 and the field oxide layer 52 by CVD to have a thickness of 50 nm.

Then, as shown in FIG. 15B, recesses 55 are formed on the field oxide layer 52 along bit lines, described later, by patterning the first amorphous silicon layer 54.

Next, steps of manufacturing the structures shown in FIG. 15C and FIG. 16A will be explained hereunder.

A SiO2 film of 6.5 nm thickness is formed by thermally oxidizing the surface of the first amorphous silicon layer 54, then a silicon nitride layer of 10 nm thickness is formed on the SiO2 film by CVD, and then another SiO2 film is formed by oxidizing the surface of the silicon nitride layer. Thus, the oxide film, the nitride film, and the oxide film are formed in sequence on the first amorphous silicon layer 54. The film having such three-layered structure is called an ONO layer 56 hereinafter.

In turn, a second phosphorus (impurity)-doped amorphous silicon layer 57 is formed on the ONO film 56 by CVD to have a thickness of 120 nm. A tungsten silicide layer 58 is grown up to a 150 nm thickness on the second amorphous silicon layer 57 by CVD.

Then, as shown in FIG. 16B, respective layers from the tungsten silicide layer 58 to the first amorphous silicon layer 54 are patterned using a sheet of mask. Word lines 60a, 60b made of the second amorphous silicon layer 57 and the tungsten silicide layer 58 and floating gates 59a, 59b made of the first amorphous silicon layer 54 are formed by this patterning.

Two word lines 60a, 60b pass through on the silicon substrate 11 in one region A surrounded by the field oxide layer 52. The floating gates 59a, 59b are formed below the word lines 60a, 60b in the region A to put the ONO layer 56 therebetween. Two floating gates 59a, 59b in the region A are separated from different floating gates 59a, 59b in the adjacent region B. The word lines 60a, 60b serve as control gates of the transistor in the region A.

After this, impurity is introduced into the region A surrounded by the second field oxide layer 52 by using the word lines 60a, 60b as a mask and is then thermally diffused. Accordingly, impurity diffusion regions 61 to 63 are formed in three regions on both sides of a pair of word lines in the region A respectively. Thus, two EEPROMs are formed in the region A.

In turn, as shown in FIG. 16C, a protection insulating film 64 made of SiO2, PSG, or the like is formed on the word lines 60a, 60b and the second field oxide layer 16. Opening portions 65 are then formed respectively on two impurity diffusion regions 61, 63 near both ends in the region A by patterning the protection insulating film 64

As shown in FIG. 16D, a metal film 66 made of tungsten, etc. is then formed in the opening portions 65 and on the protection insulating film 64. As shown in FIG. 16D, bit lines BL are then formed by patterning the metal film 66. The bit lines BL extend substantially orthogonally to the word lines 60a, 60b and are connected to the impurity diffusion layers 61, 63.

What is claimed is:

1. A method for manufacturing a semiconductor device including fabricating semiconductor device, comprising
immersing said substrate in a liquid held in a one-bath type liquid tank and washing it therein,
pulling said substrate up from said liquid tank into the atmosphere of an inert gas, and
drying said substrate in said atmosphere of the inert gas.

2. A method for manufacturing a semiconductor device including manufacturing a semiconductor device including fabricating semiconductor device, according to claim 1, wherein said substrate is a semiconductor substrate.

3. A method for manufacturing a semiconductor device including fabricating semiconductor device, comprising
placing a liquid in a liquid tank,
immersing said substrate in said liquid,
pulling up said substrate from said liquid tank into the atmosphere containing a first gas,
changing said liquid in said liquid tank to water,
immersing said substrate in said water,
changing said first gas in said atmosphere to an alcohol, and
pulling up said substrate into said atmosphere containing said alcohol and drying the surface of said substrate therein.

4. A method for manufacturing a semiconductor device including fabricating semiconductor device, according to claim 3, wherein said liquid to be placed in said liquid tank is a chemical solution or water.

5. A method for manufacturing a semiconductor device including fabricating semiconductor device, according to claim 3, wherein said liquid is water and said liquid tank contains a chemical solution before said placement of water therein.

6. A method for manufacturing a semiconductor device including fabricating semiconductor device, according to claim 3, wherein said first gas is an inert gas.

7. A method for manufacturing a semiconductor device including fabricating semiconductor device, according to claim 6, wherein a water shower is projected on said substrate in said atmosphere containing said inert gas during the exposure of said substrate to said atmosphere.

8. A method for manufacturing a semiconductor device including fabricating semiconductor device, according to claim 3, wherein said water is caused to overflow said liquid tank during the immersion of said substrate in said water.

9. A method for manufacturing a semiconductor device including fabricating semiconductor device, according to claim 3, wherein said substrate is a semiconductor substrate.

10. An apparatus for fabricating semiconductor device provided with a liquid tank for holding a chemical solution or water for the immersion of said substrate therein, which apparatus is characterized by having disposed in part of said liquid tank a liquid reservoir for receiving the liquid overflowing said liquid tank.

11. An apparatus for fabricating semiconductor device according to claim 10, wherein said liquid reservoir is fitted to the bottom part of said liquid tank.

12. An apparatus for fabricating semiconductor device according to claim 10, wherein said liquid reservoir is fitted as divided into a plurality of stages to the outer wall of said liquid tank.

13. An apparatus for fabricating semiconductor device according to claim 10, wherein said liquid reservoir is electrically grounded.

14. An apparatus for fabricating semiconductor device according to claim 10, wherein said substrate is a semiconductor substrate.

15. An apparatus for fabricating semiconductor device according to claim 10, wherein said liquid tank holds therein water containing carbon oxides.

16. An apparatus for fabricating semiconductor device provided with a liquid tank for treating said substrate with a chemical solution or water, which apparatus is characterized by said liquid tank being electrically grounded.

17. An apparatus for fabricating semiconductor device according to claim 16, wherein said substrate is a semiconductor substrate.

18. An apparatus for fabricating semiconductor device provided with a liquid tank for treating said substrate with a chemical solution or water, which apparatus is characterized in that said liquid tank is adapted to hold water containing carbon oxides and said substrate is immersed in said water to be washed.

19. An apparatus for fabricating semiconductor device, comprising
a wet chamber provided with a first rotatable wafer mounting part for mounting a substrate thereon and first liquid feed means for feeding a liquid to said substrate,
a dry treating chamber provided with a second wafer mounting part for mounting said substrate thereon, gas feed means for feeing a gas to said substrate, and gas discharge means for evacuating the interior of said chamber,
a liquid storage chamber provided with a liquid tank for holding a liquid, wafer moving means for introducing said substrate into said liquid tank, second liquid feed means for feeing a liquid to said liquid tank, and means for introducing an alcohol,
a vacuum conveyor path connected to all of said first spin type wet chamber, said dry treading chamber, and said liquid tank chamber, and
wafer conveying means disposed in said vacuum conveyor path and adapted to convey said substrate.

20. An apparatus for fabricating semiconductor device, according to claim 19, wherein said wet chamber has disposed therein a spinner for mounting said substrate.

21. An apparatus for fabricating semiconductor device, according to claim 19, wherein two wet chambers are disposed therein.

22. An apparatus for fabricating semiconductor device, according to claim 19, which further comprises a second spin type wet chamber provided with a third rotatable wafer mounting part for mounting said substrate and
third liquid feed means for feeding a liquid to said substrate.

23. An apparatus for fabricating semiconductor device, according to claim 19, wherein a buffer chamber for temporary storage of said substrate is adjoined to said vacuum conveyor path.
